(19) United States
(12) Patent Application Publication
(10) Pub. No.: US 2026/0254434 A1
(43) Pub. Date: Aug. 27, 2026

(54) ELASTIC SURFACE WAVE DEVICE HAVING ELECTRODES EMBEDDED IN A PIEZOELECTRIC LAYER, AND DESIGN AND PRODUCTION THEREOF

(71) Applicant: Soitec, BERNIN (FR)

(72) Inventors: Alexandre Clairet, BERNIN (FR); Thierry Laroche, BERNIN (FR); Sylvain Ballandras, BERNIN (FR)

(21) Appl. No.: 18/861,506

(22) PCT Filed: Apr. 28, 2023
(86) PCT No.: PCT/EP2023/061211

§ 371 Date: Oct. 29, 2024

(30) Foreign Application Priority Data
Apr. 29, 2022 (FR) 2204085

(51) Int. Cl. H03H 9/02; H03H 9/145; H03H 9/25

(52) U.S. Cl. CPC H03H 9/02842; H03H 9/02559; H03H 9/02566; H03H 9/02574; H03H 9/14538; H03H 9/25

(57) ABSTRACT

An elastic surface wave device includes a piezoelectric layer, first and second interdigitated electrodes embedded in the piezoelectric layer, and a substrate carrying the piezoelectric layer and the electrodes. The substrate satisfies both of the following conditions: an attenuation of an elastic mode having an electrode in the piezoelectric layer is less than 0.1 dB/λ; and a speed ratio between a volumetric elastic shear mode for the substrate and a fundamental elastic shear mode for the piezoelectric layer is smaller than a predetermined speed ratio having a value equal to 1. The substrate is chosen from among gallium arsenide and a glass having a Young's modulus of between 60 GPa and 180 GPa, a Poisson's ratio of between 0.15 and 0.35, and a density of between 2000 kg/m³ and 6000 kg/m³.

### CROSS-REFERENCE TO RELATED APPLICATIONS

This application is a national phase entry under 35 U.S.C. § 371 of International Patent Application PCT/EP2023/061211, filed Apr. 28, 2023, designating the United States of America and published as International Patent Publication WO 2023/209138 A1 on Nov. 2, 2023, which claims the benefit under Article 8 of the Patent Cooperation Treaty of French Patent Application Serial No. FR2204085, filed Apr. 29, 2022.

### TECHNICAL FIELD

Embodiments of the present disclosure relate to surface acoustic wave (SAW) devices with composite structures incorporating electrodes embedded in a thin layer of piezoelectric material, and related methods.

### BACKGROUND

Elastic surface acoustic wave devices, or SAW devices, are used in a wide range of applications, particularly in electronics, where they form the core element of filters, oscillators, delay lines and transformers.

Piezoelectric materials generate an electrical voltage when deformed by mechanical stress, and conversely deform when an electrical voltage is applied.

Consequently, when an alternating electrical signal is applied to one or more electrodes in contact with a piezoelectric layer, a mechanical signal (that is, an oscillation or vibration) is generated at this piezoelectric material: the electrical signal is transformed into a mechanical signal.

The mechanical signal propagating in the piezoelectric material exhibits a frequency dependence on the electrical alternating signal, which is a function of the characteristics of the electrode(s), the properties of the piezoelectric material, and other factors such as the shape of the elastic wave device and other structures making up the device.

Elastic wave devices exploit this frequency dependence to provide one or more functions by means of surface acoustic wave (SAW) resonators or SAW transducers, which are increasingly used to form, for example, so-called “SAW filters” used in the transmission and reception of RF signals for telecommunications applications.

A SAW filter comprises at least one elastic surface acoustic wave transducer, potentially surrounded by reflecting mirrors made up of periodically arranged electrodes and satisfying the so-called Bragg condition, forming a resonator by reflection of the waves emitted by the transducer in phase towards the latter. The filter can advantageously be composed of a combination of such resonators and can also feature at least one input transducer and at least one output transducer. It may utilize electrical or elastic couplings between resonators or transducers. Its temporal response can be finite (in the case of conventional transversal filters) or infinite (in the case of resonator filters). In all cases, these structures are referred to indiscriminately as SAW filters by the person skilled in the art.

The geometry and dimensions of the transducers, and the types and shapes of the materials used, determine the characteristics of the SAW filter, such as coupling and reflection factors, quality factor Q, bandwidth, spurious responses, suppression of resonances of higher orders than the resonance used, and temperature dependence of the mode used.

International Patent Application Publication No. WO 2021/053401 discloses a SAW transducer comprising electrodes forming interdigitated combs and having the particularity of being embedded in the piezoelectric layer, as shown by FIG. 1.

The acoustic impedance of these electrodes is lower than that of the piezoelectric layer, so as to contain the propagation of a shear mode essentially within the electrode volume by reflection against the electrode walls at a frequency higher than that of the fundamental shear mode for the piezoelectric layer, referred to as the “electrode mode.”

However, the interdigitated comb configuration of the electrodes and the excitation by means of opposite polarities of two adjacent prongs of the combs enables the electrode mode to generate, in the piezoelectric layer, coherent propagating shear waves leading to a resonance phenomenon for an operational elastic wavelength λ.

The transducer's operational elastic wavelength λ is related to the transducer's resonant frequency fᵣ by the relationship fᵣ=v/λ, where v represents the propagation velocity in the piezoelectric layer.

A SAW transducer of International Patent Application Publication No. WO 2021/053401 enables the use of higher frequencies than those employed in conventional SAW transducers, which are usually based on thin-film electrodes located on the surface of the piezoelectric layer and for which the elastic waves have frequencies derived from that layer's eigenmodes. In the remainder of this document, references to conventional SAW devices or transducers will refer to such transducers, based on thin-film electrodes located on the surface of the piezoelectric layer.

This is because the resonant frequency fᵣ of the electrode mode is defined by the resonance of the elastic waves in the electrode volumes, which occurs at a higher frequency than the natural modes of the piezoelectric layer in conventional devices.

However, characteristics other than the resonant frequency fᵣ are important for practical applications, particularly the purity of the frequency response, and the person skilled in the art is looking for optimization and/or alternatives in the choice of materials suitable for forming the substrate of a SAW transducer to employ an electrode mode.

### BRIEF SUMMARY

A first object of the present disclosure is to provide elastic surface acoustic wave devices capable of employing an electrode mode and exhibiting acceptable performance for practical applications, with in particular a spectral purity of frequency response that is acceptable from the standpoint of practical applications and conditioned by the attenuation of the fundamental shear mode for the piezoelectric layer by the substrate.

A second object of the present disclosure is to provide a method for selecting a substrate suitable for a SAW device comprising electrodes embedded in a piezoelectric layer and designed to operate by excitation of an elastic mode specific to these electrodes.

A third object of the present disclosure is to provide a production method integrating the choice of a suitable substrate in the production of a SAW device.

To these ends, the disclosure relates to an elastic surface wave device comprising a piezoelectric layer, electrodes embedded in the piezoelectric layer, and a substrate carrying the piezoelectric layer and the electrodes, the substrate satisfying both of the following conditions:
an attenuation of an elastic mode having an electrode in the piezoelectric layer is less than 0.1 dB/λ; and
a speed ratio between a speed of a volumetric elastic shear mode for the substrate and a fundamental elastic shear mode for the piezoelectric layer is smaller than a predetermined speed ratio having a value equal to 1,
the substrate being chosen from among gallium arsenide and a glass having a Young's modulus of between 60 GPa and 180 GPa, a Poisson's ratio of between 0.15 and 0.35, and a density of between 2000 kg/m³ and 6000 kg/m³.

Such a SAW device with embedded electrodes, intended to operate by excitation of a natural elastic mode of these electrodes, will operate satisfactorily if it employs a substrate chosen in such a way that, in combination with a piezoelectric layer and embedded electrodes, the two conditions on attenuation and the ratio of speeds defined above are met, that is, the propagating electrode mode is predominant over the fundamental shear mode for the piezoelectric layer.

Compliance with the condition on attenuation, or propagation losses, ensures that the substrate is capable of accessing the elastic electrode mode, that is, that the elastic electrode mode can actually be excited and propagate properly in the piezoelectric layer, and be used in SAW devices as described above, comprising an electrode embedded in the piezoelectric layer.

One advantage of this elastic electrode mode is that it allows access to relatively high operating frequencies (e.g. over 3 GHZ), for devices that do not require production methods at the limits of what is currently technically feasible, and whose reliability and robustness are assured.

According to other non-limiting features of the disclosure, taken either individually or in any technically feasible combination:
a ratio of an attenuation of the fundamental shear mode for the piezoelectric layer to the attenuation of the elastic electrode mode is greater than 10;
the electrodes pass completely through the piezoelectric layer;
the substrate is formed from a glass having a Young's modulus of between 60 GPa and 80 GPa, a Poisson's ratio of between 0.15 and 0.25, and a density of between 2100 kg/m³ and 2400 kg/m³;
the substrate is formed from gallium arsenide.

The disclosure extends to a method for determining the matching of a substrate to an elastic surface wave device comprising a piezoelectric layer, electrodes embedded in the piezoelectric layer and the substrate, the method being implemented by way of a computer system and comprising the step of emitting a signal representative of a matching of the substrate to the elastic surface wave device, when:
an attenuation of an elastic mode having an electrode in the piezoelectric layer is less than 0.1 dB/λ; and
a speed ratio between a speed of a volumetric elastic shear mode for the substrate and a fundamental elastic shear mode for the piezoelectric layer is smaller than a predetermined speed ratio having a value equal to 1.

According to other non-limiting features of the disclosure, taken either individually or in any technically feasible combination:
the computer system comprises a computer calculation unit and a computer memory functionally in communication with the computer calculation unit and storing a database storing parameters relating to the geometry and nature of the electrodes, the piezoelectric layer, and the substrate, the computer calculation unit implementing the following steps:
   retrieving data from the computer memory database, including parameters relating to the geometry and nature of the electrodes, the piezoelectric layer and the substrate;
   calculating the attenuation of an elastic electrode mode in the piezoelectric layer, based on the retrieved data;
   comparing the attenuation of the elastic electrode mode in the piezoelectric layer with a predefined attenuation value of 0.1 dB/λ;
   calculating a speed ratio between a volumetric elastic shear mode for the substrate and a fundamental elastic shear mode for the piezoelectric layer, from the retrieved data;
   comparing the speed ratio with a predetermined speed ratio value;
   emitting the signal representative of a matching of the substrate to the elastic surface wave device, when:
      the attenuation of the electrode elastic mode in the piezoelectric layer is smaller than the predefined attenuation value; and
      the speed ratio is smaller than the predetermined speed ratio value.

According to other non-limiting features of the disclosure, applying to the device as well as to the method, taken alone or in any technically feasible combination:
the predetermined value of the speed ratio is equal to 0.9;
the attenuation Attn of the electrode elastic mode is defined by the formula

$$Attn = - 40 π \frac{π}{π - Δ} \frac{{f}_{h} - {f}_{b}}{{f}_{h} + {f}_{b}} log ( e )$$

where, for an electrode excitation generating a propagating mode of an elastic shear wave, Δ is the acoustic reflection coefficient per electrode, the log function represents the decimal logarithm such that log (e) ~0.434 and fₕ and f_{b} are frequencies associated with a resonance of the elastic shear wave at which an electrical susceptance of the elastic wave device reaches its highest and lowest points, respectively.

The disclosure also extends to a method for producing the SAW device with electrodes embedded in the piezoelectric layer, which method comprises the determination method.

### BRIEF DESCRIPTION OF THE DRAWINGS

Other features and advantages of the disclosure will emerge from the following detailed description of embodiments of the disclosure with reference to the accompanying figures, in which:

FIG. 1 shows a schematic plan view of a SAW transducer with electrodes embedded in a piezoelectric layer;

FIG. 2 schematically shows the SAW transducer of FIG. 1 in a cross-sectional view of the transducer along the plane passing through the segment indicated by Y-Y′ on the plan view and perpendicular thereto;

FIG. 3 shows a possible electrode geometry for the SAW transducer shown in FIG. 1, used for computer modeling of this transducer;

FIG. 4 shows a simulation plot of the electrical admittance of a SAW resonator centered on the resonance of one electrode mode;

FIG. 5 shows a simulation plot of the electrical admittance of a SAW transducer showing the effects of a volumetric elastic shear mode for the substrate and a fundamental elastic shear mode for the piezoelectric layer;

FIG. 6 shows a SAW filter in ladder mode;

FIG. 7 shows a theoretical transfer function for a first example of a ladder filter;

FIG. 8 shows a theoretical transfer function for a second example of a ladder filter;

FIG. 9 shows a substrate evaluation diagram for a SAW device;

FIG. 10 shows a device for implementing a method corresponding to the diagram in FIG. 9; and

FIG. 11 shows a method for manufacturing a SAW device.

### DETAILED DESCRIPTION

The working frequency of elastic surface wave devices (SAW devices) is defined by the synchronous frequency of the transducers.

Various approaches can be taken to increase the operating frequency of elastic surface wave devices.

A first approach is to reduce the wavelength of the elastic waves used in the devices, the frequency being inversely proportional to this wavelength.

However, this method is limited by the current technical frontiers of UV lithography in use in the SAW filter industry, which do not allow electrodes with a width of less than a few hundred nanometers to be manufactured, the above-mentioned wavelength being equal to twice the period p of the interdigitated electrodes of SAW devices.

In addition, problems can arise with the structural stability of the electrodes: the power handling of these devices is insufficient to meet current requirements, due to the small size of the electrodes and the resulting power density.

A second approach to increasing the operating frequency of SAW devices is to increase the speed of elastic waves in the device, the frequency being proportional to this speed.

However, the velocity of elastic waves in SAW devices is limited by the properties of the substrate materials.

To overcome this limitation, it is possible, for example, to use guided waves on composite substrates.

The solution contemplated in the present disclosure is based on the integration of electrodes in the piezoelectric layer to increase the speed of the working mode, that is, the speed of the elastic wave utilized in the SAW device in question.

It is understood in the present disclosure that a piezoelectric layer is a layer consisting of one or more piezoelectric materials, that is, a layer of one or more materials possessing piezoelectric characteristics.

We consider a pair of interdigitated electrodes (or IDTs for Inter-Digitated Transducer) of similar general shape to those used in a conventional SAW transducer with electrodes resting on the piezoelectric layer, with the difference that here the electrodes are embedded in the piezoelectric layer.

Thanks to the integration of IDTs in the piezoelectric layer, an elastic shear mode confined predominantly to each of the electrodes (known as the “electrode mode”) can be excited. The acoustic impedance of these electrodes is lower than that of the piezoelectric layer.

This wave is polarized parallel to the substrate and perpendicular to the electrode sidewalls, and produces a shear displacement in the direction orthogonal to the propagation direction, with significant advantages over conventionally employed surface waves, particularly in terms of achievable frequency for a propagating elastic mode for a given geometry and dimensions of a SAW transducer, as detailed in International Patent Application Publication No. WO21053401.

One problem to be solved is that there is no standard or table of material characteristics to which to refer to determine the materials suitable for the manufacture of such a transducer.

The choice of substrate is particularly critical, since it affects the very possibility of using the transducer according to the electrode mode and, beyond that, the performance of the device.

In this context, numerous materials have been tested as candidates for use as substrates, and which characteristics could serve as selection criteria have been investigated.

In so doing, characteristics were determined that are predictive of the suitability of a substrate material for a SAW device designed to implement an electrode mode.

Two features have been isolated, enabling a substrate to be selected in such a way that a SAW device comprising the selected substrate will actually be capable of suitably implementing an electrode mode.

“Suitably” means that the electrode mode propagates predominantly with respect to the fundamental shear mode for the piezoelectric layer, that is, the ratio of the attenuation (or attenuation coefficient) of the fundamental mode of the piezoelectric layer to the attenuation of the electrode mode is preferably greater than 10, more preferably greater than 50, even more preferably greater than 100. Under these conditions, it is possible to operate an electrode mode with attenuation less than or equal to that of a SAW mode in a conventional transducer.

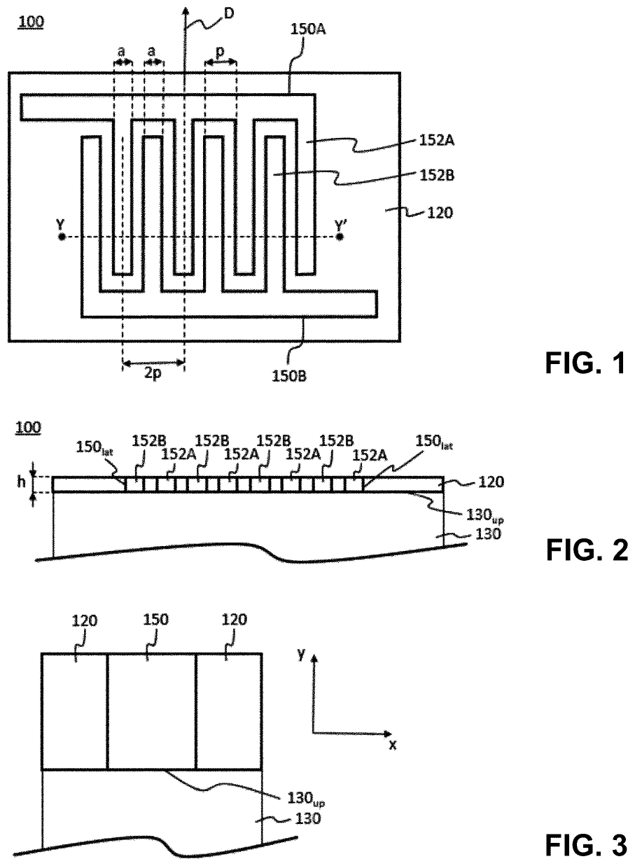

As shown in FIGS. 1 and 2, the SAW devices 100 considered in this example consist of a SAW transducer made up of a piezoelectric layer 120 of thickness h, a first interdigitated electrode 150A and a second interdigitated electrode 150B, embedded in the piezoelectric layer 120 and of height h corresponding here to the thickness of the piezoelectric layer, and a substrate 130 supporting the piezoelectric layer and the electrodes.

Although the electrodes are preferably electrodes that completely penetrate the piezoelectric layer and are of the same thickness as the latter, that is, they are in direct contact with the substrate 130, or with an intermediate layer interposed between the substrate 130 and the piezoelectric layer 120, and do not protrude above the piezoelectric layer 120, as shown in FIGS. 2 and 3, other geometries are acceptable as long as the electrode mode can excite the piezoelectric layer: it is sufficient for the electrodes to extend partially through the piezoelectric layer; they could also protrude above the piezoelectric layer. In this way, they can penetrate the entire piezoelectric layer and exceed its height.

In the case of a non-through electrode, electrical charges that do not appear in the case of a through electrode will appear under the electrodes. This means that the overall contribution of charges from one electrode to the other in the periodic interdigitated network may be less than in the case of a through electrode. As a result, a SAW device with through electrodes will have a stronger, and, therefore, better, electromechanical coupling than a SAW device with non-through electrodes. Non-through electrodes are also likely to couple a residue of a fundamental mode that could adversely affect the spectral purity of the frequency response.

In the present embodiment, there is direct contact between the substrate 130 and each of the piezoelectric layer 120 and the first and second interdigitated electrodes 150A and 150B. However, it is entirely possible to have an intermediate layer covering the substrate and interposed between it and each of the piezoelectric layer 120 and the first and second interdigitated electrodes 150A and 150B, as already mentioned above.

This intermediate layer may comprise, for example, a bonding layer used to attach the piezoelectric layer to the substrate, such as a silicon dioxide layer between 10 nm and 400 nm thick, preferably between 20 nm and 150 nm, for example, 30 nm thick, without this being restrictive.

It should be noted that all the calculations and conclusions mentioned in this description also apply to situations where this intermediate layer is present and for the different electrode geometries mentioned above, identical conclusions for the different figure cases were obtained.

The pair of electrodes comprises a first interdigitated electrode 150A and a second interdigitated electrode 150B, each with a lower face in direct or non-direct contact with an upper face 130ᵤₚ of the substrate and side faces 150ₗₐₜ in direct or non-direct contact with the piezoelectric layer 120.

As with the intermediate layer between the substrate and the piezoelectric layer, it is also possible to have a layer between the electrodes and the piezoelectric layer, as well as between the underside of the electrodes and the substrate or the intermediate layer, without affecting the conclusions on the choice of substrate as set forth herein.

First and second interdigitated electrodes 150A and 150B comprise respective fingers 152A and 152B extending in the same direction D, so as to form a periodic structure of period p in a direction perpendicular to direction D, wherein the fingers of the two electrodes are placed alternately, so as to form a pair of interdigitated electrodes or IDTs.

The wavelength λ of the elastic mode excited by the transducer is equal to twice the period p, that is, 2p, the transducer operating under Bragg conditions for this particular wavelength, which corresponds to the operational elastic wavelength mentioned above.

This wavelength is also understood as the distance separating the central axes of extension of two adjacent fingers of the same electrode, that is, axes each forming an axis of symmetry of the corresponding finger in plan view, this axis being parallel to the direction D of extension of the fingers.

The structure described with reference to FIG. 1 has been computer-modeled, for example, using a finite element method, as shown in FIG. 3, which shows a period of the model in the direction x parallel to the substrate surface and perpendicular to the direction D, with only a small portion of the substrate shown in the direction y perpendicular to the substrate surface, the substrate being considered semi-infinite.

This model was used to simulate with a computer the electromechanical characteristics of SAW devices as a function of the materials used, and thus test the relevance of numerous characteristics in the selection of the material of the substrate.

It was found that two characteristics can be used to predict the suitability of a given substrate for the manufacture of a SAW device designed to employ an electrode mode: first, the attenuation of the elastic electrode mode in the substrate, and second, the attenuation of the fundamental shear mode for the piezoelectric layer. These parameters are simulated as a function of the piezoelectric layer and the electrodes.

### First Condition—Attenuation of the Electrode Mode

A substrate beneath the piezoelectric layer can, if adapted to the characteristics (natures, geometries) of the embedded electrodes and the piezoelectric layer, improve confinement and propagation of the electrode mode, but not all materials are suitable for forming a substrate that enables the structure shown in FIG. 1 and modeled as shown in FIG. 3 to properly utilize an electrode mode, that is, the electrode mode has an attenuation less than or equal to that of the mode utilized in a SAW device equipped with surface electrodes, for example, for filter design.

In this way, the electrode mode propagates through the piezoelectric layer and is attenuated by radiation into the substrate, which is why it is so important to the device's characteristics.

Among the characteristics considered and used to simulate the behavior of SAW devices, it turned out that those whose substrate is such that the attenuation of the electrode mode in the piezoelectric layer is less than the attenuation limit value of 0.1 dB/λ, preferably 0.05 dB/λ, more preferably 0.01 dB/λ, are the substrates enabling the device to properly utilize an electrode mode. This attenuation limit value has been chosen in such a way that a SAW device designed to operate with an electrode mode and comprising a substrate that matches the characteristics of the electrodes and the piezoelectric layer, thus enabling this criterion to be met, has performances at least equivalent to the typical performances of a conventional SAW device based on the operation of one mode of the piezoelectric layer by way of surface electrodes, with the additional possibility of operating at higher frequencies thanks to the operation based on the electrode mode. It is to be understood here that an attenuation of an elastic electrode mode of a SAW device according to the disclosure has an attenuation less than or equal to the attenuation of a mode of a piezoelectric layer excited by means of surface electrodes.

Thus, substrates that, in combination with given electrodes and piezoelectric layer, result in electrode mode attenuation in the piezoelectric layer less than or equal to the attenuation limit value of 0.1 dB/λ, preferably 0.05 dB/λ, more preferably 0.01 dB/λ, are retained in the context of the present disclosure as suitable for excitation of the electrode mode, in the sense that the expected performance in terms of electrode mode attenuation is at least equivalent to that of a conventional SAW device based on the exploitation of one mode of the piezoelectric layer by way of surface electrodes.

Conversely, substrates that, in combination with electrodes and a given piezoelectric layer, lead to an electrode mode attenuation in the piezoelectric layer in excess of the attenuation limit value of 0.1 dB/λ are rejected as unsuitable for the excitation and operation of an electrode mode in a SAW device comprising the electrodes and piezoelectric layer. In such a configuration, a surface acoustic wave is too attenuated to propagate properly in the electrode array. The use of a device of this configuration to create a filter, for example, is not possible, as the insertion losses are too high.

A method for calculating attenuation is described in detail in the doctoral thesis by Y. Fusero “Etude théorique et expérimentale de dispositifs a ondes de surface à haute vitesse et fort couplage: application aux filtres télécom haute fréquence,” Université de Franche-comté, pp. 74-75, 2001.

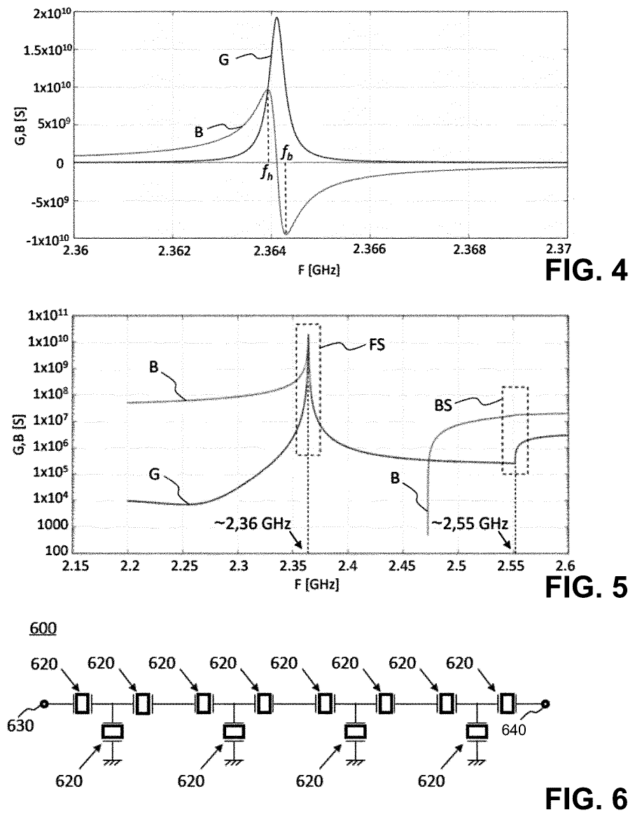

FIG. 4 shows a simulation plot of the electrical admittance of a SAW transducer in linear scales with, as a function of frequency indicated on the x-axis and extending from 2.36 to 2.37 GHz, a conductance G and the associated susceptance B indicated in Siemens per meter on the y-axis and extending between −1×10¹⁰ S/m and 2*10¹⁰ S/m.

The resonance peak of conductance G is associated with a minimum and a maximum of susceptance B at frequencies fₕ and f_{b} respectively, on either side of the peak.

The attenuation of the electrode mode in the piezoelectric layer, hereinafter referred to as Attn, can be expressed by the following equation Eq. 1:

$$Attn = - 40 π \frac{π}{π - Δ} \frac{{f}_{h} - {f}_{b}}{{f}_{h} + {f}_{b}} log e \qquad Eq . 1$$

wherein Δ is the electrode reflection coefficient, fₕ and f_{b} are respectively the frequencies of the maximum and minimum susceptance (imaginary part of the admittance) associated with the SAW device under consideration, as shown in FIG. 4.

### Second Condition—Attenuation of the Fundamental Shear Mode

Compliance with the first condition ensures that an electrode mode can be effectively excited in a SAW device and propagate under conditions similar to or close to those of an elastic wave excited by a conventional SAW device, designed to operate with a piezoelectric layer mode excited by surface electrodes.

However, this criterion alone does not guarantee the practical usability of this mode.

Indeed, the overall response of the device and the purity of the frequency response determine its performance in practical applications such as telecommunication signal filtering.

To obtain a frequency response of acceptable purity, it is particularly necessary to suppress the fundamental shear mode for the piezoelectric layer.

This suppression can be achieved by attenuating this mode in the substrate and can be evaluated using a formula identical to equation Eq. 1 above, this time applied to the fundamental shear mode for the piezoelectric layer.

It was determined through numerous simulations that the attenuation of the fundamental shear mode for the piezoelectric layer by the substrate had to be greater than or equal to 1 dB/λ for the SAW device to have an acceptable purity frequency response.

This condition reflects the fact that a substrate adapted to a given piezoelectric layer provides sufficiently strong attenuation of the mode of this piezoelectric layer so that this mode is absorbed by the substrate and does not propagate into the piezoelectric layer, which would have unacceptable effects on the purity of the frequency response, in particular, the presence of a second conductance peak with high coupling.

The value of 1 dB/λ represents a limit value at which it is still possible to have a superposition of modes likely to produce spurious responses.

As already mentioned, equation 1 can be used to calculate this attenuation in the same way as electrode mode attenuation.

Alternatively, compliance with this condition, which relates to an attenuation criterion, can be verified by way of a criterion relating to the ratio of the speed C(Subst) of a volumetric elastic shear mode for the substrate to the speed C(Piezo) of the fundamental elastic shear mode for the piezoelectric layer.

Thus, with a substrate in which this C(Subst)/C(Piezo) ratio is greater than or equal to 1 (speed of a volumetric elastic shear mode for the substrate being greater than or equal to the speed of a fundamental elastic shear mode for the piezoelectric layer), the fundamental elastic shear mode for the piezoelectric layer will tend to be guided into the piezoelectric layer rather than being absorbed by the substrate, and will, therefore, tend to deteriorate the frequency response of the device in question, in particular its spectral purity.

Such a substrate will be rejected as unsuitable for satisfactory operation of the device in question.

Conversely, a substrate wherein the C(Subst)/C(Piezo) ratio is less than 1 (that is, the speed of a volumetric elastic shear mode for the substrate is less than the speed of the fundamental elastic shear mode for the piezoelectric layer) propagates the fundamental elastic shear mode for the piezoelectric layer into the substrate volume, and the substrate absorbs the mode, preventing it from degrading the frequency response of the device in question.

Such a substrate can be used to produce and implement the device in question.

The smaller the speed ratio described above, the stronger the radiation in the substrate of the piezoelectric layer mode, and the better the spectral purity of the device's frequency response.

Although a ratio of 1 may be considered acceptable for certain applications, it is preferable to choose a ratio lower than 1, as a ratio of 0.9 already provides a clear improvement in frequency response and, therefore, device performance.

Mode speeds can be determined by measuring one or more test structures on the substrate.

Alternatively, speeds can be determined using a finite element method, more specifically FEM-BEM (Finite Element Method-Boundary Element Method), which models in two dimensions the period of a given SAW transducer, taking into account radiation effects in the substrate geometry as shown in FIG. 3.

A finite element calculation method is used to take into account the embedding of the electrodes in the piezoelectric layer, as well as the mass effect of the electrodes.

The frequency response of the given SAW transducer having been calculated according to the above method, we can obtain the speed of a volumetric elastic shear mode for the substrate and the speed of a fundamental elastic shear mode for the piezoelectric layer from the formula Eq. 2 below:

$$c = λ \times f \qquad Eq . 2$$

where c represents the speed of a wave considered, λ its wavelength, and fits frequency.

The wavelength λ is determined by the electrode geometry of the given SAW transducer and the frequency of the mode under consideration, this frequency being extractable from the frequency response of this transducer, as shown in FIG. 5.

FIG. 5 shows, for a given SAW transducer shown in FIG. 1, a simulation graph of the electrical impedance of a SAW transducer in linear scale on the x-axis and in logarithmic scale on the y-axis with, as a function of the frequency indicated on the x-axis and extending from 2.2 to 2.6 GHz, a conductance G and the associated susceptance B indicated in Siemens per meter on the y-axis, the y-axes visible on the graph extending between 100 S/m and 1×10¹¹ S/m.

The particular signatures of the volumetric elastic shear mode for the substrate and a fundamental elastic shear mode for the piezoelectric layer are indicated by BS and FS respectively on the graph.

The frequency of the bulk shear mode at around 2.55 MHz and the frequency of the fundamental shear mode at around 2.36 MHz can be derived from this graph, which can be used to calculate the speeds of these modes from equation Eq. 2 in this given SAW device.

### Method for Evaluating a Substrate

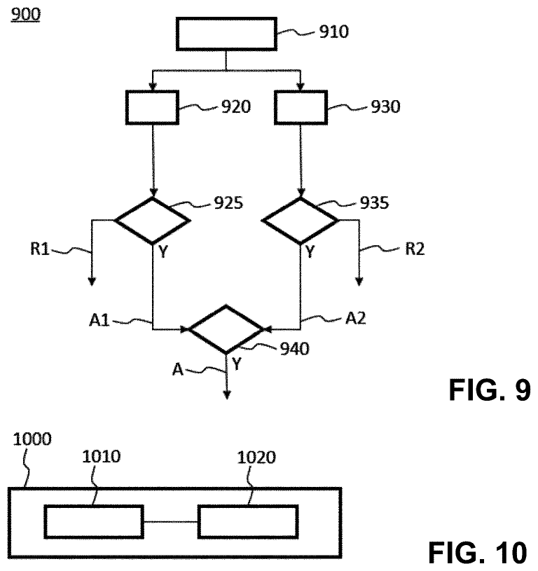

Based on the substrate acceptance conditions detailed above, a method 900 for evaluating a material for use as a substrate in a SAW device with electrodes embedded in a piezoelectric layer can be detailed, shown by the diagram in FIG. 9.

Such a method is preferably implemented by way of a computer system 1000 shown in FIG. 10, comprising a computer calculation unit 1010 and a computer memory 1020 functionally in communication with the computer calculation unit and storing a database storing parameters relating to the geometry and nature of the electrodes, the piezoelectric layer, and the substrate.

In step 910, the computer calculation unit 1010 retrieves data from the computer memory database 920, including parameters relating to the geometry and nature of the electrodes, the piezoelectric layer, and the substrate.

This data includes, in particular, the characteristics of the material considered for the substrate: its nature and, if applicable, its crystallographic orientation.

In step 920, the computer unit calculates an attenuation of an electrode elastic mode in the piezoelectric layer from the data retrieved in step 910.

In step 925, the computer unit compares the attenuation calculated in step 920 with a predefined attenuation value.

If the attenuation of the elastic electrode mode is greater than or equal to the predefined attenuation value, then the computer unit emits a signal R1 rejecting the substrate, which is not suitable for enabling the SAW device to implement an electrode mode by acousto-electric excitation.

If the attenuation of the elastic electrode mode is smaller than the predefined attenuation value (situation indicated by “Y”), then the computer unit emits a signal A1 of partial acceptance of the substrate, which meets at least one of the conditions necessary for its acceptance, which, in this case, is that of its ability to enable the SAW device to implement an electrode mode by acousto-electric excitation.

This predefined attenuation value can be 1 dB/λ, for the reasons explained above.

In the step 930, the computer unit calculates a speed ratio between a volumetric elastic shear mode for the substrate and a fundamental elastic shear mode for the piezoelectric layer, from the retrieved data.

In the step 935, the computer unit compares the speed ratio calculated in step 930 with a predetermined speed ratio value.

If the speed ratio is smaller than the predetermined speed ratio value (situation indicated by “Y”), then the computer unit emits a signal A2 of partial acceptance of the substrate, which meets at least one of the conditions necessary for its acceptance, which, in this case, is that of its ability to attenuate the fundamental shear mode for the piezoelectric layer sufficiently for the SAW device in question to present acceptable performance in terms of the purity of its frequency response.

If the speed ratio is greater than or equal to the predetermined speed ratio value, then the computer unit emits a signal R2 rejecting the substrate as being unsuitable for acceptable operation of the SAW device.

The predetermined speed ratio value can be equal to 1, preferably equal to 0.9 as explained above.

In step 940, the computer unit checks whether the two signals A1 and A2 have indeed been emitted and, if so, emits a signal A representative of an acceptance of the substrate in the sense that it fulfills the two conditions necessary to be considered suitable for forming a SAW device intended to operate using an electrode mode.

This substrate evaluation method enables the selection of a substrate to be combined with given electrodes and a piezoelectric layer to obtain a SAW device designed to implement an electrode mode, without having to go through the time-consuming and costly phase of manufacturing test samples and characterizing them from an electro-acoustic point of view, or at least enables the type of samples to be targeted for production.

It should be noted that these substrate acceptance conditions apply particularly to cases where the electrodes are made of a relatively light metal, such as aluminum or an aluminum alloy (e.g. 2% copper aluminum alloy AlCu_{2%}), and where the piezoelectric layer is formed of lithium tantalate LiTaO₃ or lithium niobate LiNbO₃, according to the geometry described in FIGS. 1 and 2.

However, these conditions remain valid for other electrode and piezoelectric layer materials, and for geometries not limited to those shown in FIGS. 1 and 2.

### Method for Producing a SAW Device.

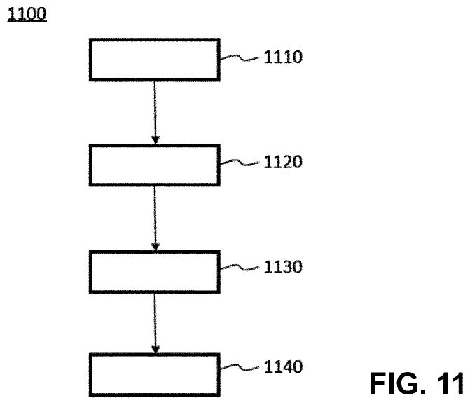

The substrate evaluation process described above can be integrated into a method 1100 for producing a SAW device, shown in the diagram in FIG. 11, wherein the first step 1110 involves selecting the substrate for a device with characteristics already partially defined, that is to say, for an already fixed geometry and materials of the piezoelectric layers and electrodes.

This first step 1110 may involve implementing the method 900 shown in FIG. 9.

In step 1120, a piezoelectric layer is formed directly on a substrate selected as acceptable in step 1110.

Alternatively, in step 1120, the piezoelectric layer can be obtained separately, then attached to the substrate by molecular bonding.

In step 1130, the piezoelectric layer is prepared to accommodate the electrodes, for example, by etching a predetermined pattern into the thickness of the piezoelectric layer.

In step 1140, the electrodes are formed in the piezoelectric layer by conventional methods.

By proceeding according to this method, we can expect to obtain a SAW device capable of utilizing an electro-acoustic excitation electrode mode.

Example substrates

Compliance with the first and second characteristics defined above has been verified for a set of transducers with the geometry shown in FIGS. 1 and 2.

In a first series of transducers, a quartz glass substrate, or “fused quartz,” was considered in association with electrodes of a 2% copper aluminum alloy AlCu_{2%} and a piezoelectric layer comprising lithium tantalate LiTaO₃ or lithium niobate LiNbO₃, for SAW transducers designed to operate at 4.8 GHz or 2.4 GHz.

The simulation results are shown in Table 1 below.

TABLE 1

| Piezoelectric material | LiTaO₃ | LiTaO₃ | LiNbO₃ | LiNbO₃ |
|---|---|---|---|---|
| and operating frequency | 4.8 GHz | 2.4 GHz | 4.8 GHz | 2.4 GHz |
| C(Subst) in m/s | 3766 | | | |
| C(Piezo) in m/s | 4.658 | 4.620 | 3.876 | 3.797 |
| C(Subst)/C(Piezo) | 0.81 | 0.82 | 0.97 | 0.99 |
| | (OK) | (OK) | (OK) | (OK) |
| Attenuation (Elec) | 3.18.10⁻³ | 2.54.10⁻² | 9.31.10⁻² | 7.72.10⁻² |
| in dB/λ | (OK) | (OK) | (OK) | (OK) |
| Attenuation (Piezo) | 3.61 | 6.12 | 3.06 | 4.09 |
| in dB/λ | (OK) | (OK) | (OK) | (OK) |
| Substrate status | OK | OK | OK | OK |

C(Subst) and C(Piezo) indicate respectively the speed of a volumetric elastic shear mode for the substrate and the speed of a fundamental elastic shear mode for the piezoelectric layer, C(Subst)/C(Piezo) indicates the ratio of these speeds.

Attenuation (Elec) and Attenuation (Piezo) indicate respectively the attenuations of an elastic electrode mode in the piezoelectric layer and of the fundamental mode of the piezoelectric layer in the substrate.

Comments (OK) indicate that the substrate meets the condition concerned by the corresponding box in the table, that is, one of the attenuation or speed ratio criteria detailed above.

We find here that it is possible to use quartz glass as a substrate for each of the SAW transducers considered, which the table indicates by a substrate status of “OK.”

In a second series of transducers, a commercial Planoptik Eagle XG glass with a Young's modulus of 64 GPa, a Poisson's ratio of 0.2 and a density of 2200 kg/m³ is used instead of the quartz glass of the first series, all other parameters remaining the same.

The simulation results are shown in Table 2 below.

TABLE 2

| Piezoelectric material | LiTaO₃ | LiTaO₃ | LiNbO₃ | LiNbO₃ |
|---|---|---|---|---|
| and operating frequency | 4.8 GHz | 2.4 GHz | 4.8 GHz | 2.4 GHz |
| C(Subst) in m/s | 3531 | | | |
| C(Piezo) in m/s | 4.702 | 4.704 | 3.966 | 3.772 |
| C(Subst)/C(Piezo) | 0.75 | 0.75 | 0.89 | 0.94 |
| | (OK) | (OK) | (OK) | (OK) |
| Attenuation (Elec) | 3.77.10⁻³ | 1.41.10⁻² | 9.94.10⁻² | 4.95.10⁻² |
| in dB/λ | (OK) | (OK) | (OK) | (OK) |
| Attenuation (Piezo) | 3.66 | 5.40 | 5.12 | 7.05 |
| in dB/λ | (OK) | (OK) | (OK) | (OK) |
| Substrate status | OK | OK | OK | OK |

We find that it is possible to use this glass as a substrate for each of the SAW transducers under consideration.

In a third series of transducers, we consider an AT-cut quartz substrate (IEEE notation) (YXl)/36° instead of the quartz glass of the first series, with all other parameters remaining the same.

The simulation results are shown in Table 3 below.

TABLE 3

| Piezoelectric material | LiTaO₃ | LiTaO₃ | LiNbO₃ | LiNbO₃ |
|---|---|---|---|---|
| and operating frequency | 4.8 GHz | 2.4 GHz | 4.8 GHz | 2.4 GHz |
| C(Subst) in m/s | 5103 | | | |
| C(Piezo) in m/s | 4.728 | 4.930 | 4.242 | 4.594 |
| C(Subst)/C(Piezo) | 1.08 | 1.04 | 1.20 | 1.11 |
| | (NOK) | (NOK) | (NOK) | (NOK) |
| Attenuation (Elec) | 2.63.10⁻³ | 1.08.10⁻² | 7.43.10⁻² | 2.13.10⁻² |
| in dB/λ | (OK) | (NOK) | (OK) | (NOK) |
| Attenuation (Piezo) | 4.39.10⁻³ | 6.64.10⁻⁵ | 1.17.10⁻³ | 6.18.10⁻³ |
| in dB/λ | (NOK) | (NOK) | (NOK) | (NOK) |
| Substrate status | NOK | NOK | NOK | NOK |

We note here that it is not possible to use AT-cut quartz as a substrate for any of the SAW transducers under consideration, the substrates being rejected and their statuses then indicated as NOK.

In fact, although the condition on electrode mode attenuation in the substrate is met for operation at 4.8 GHz for both types of piezoelectric layer (LiTaO₃ and LiNbO₃), the condition on attenuation of the piezoelectric layer's natural mode is not satisfied, as indicated by the comments (NOK).

The table thus indicates with (NOK) the violation of the condition on the attenuation of the fundamental mode of the piezoelectric layer in the substrate, which must be greater than or equal to 1 dB/λ to meet the condition.

The table also indicates with (NOK) the violation of the condition on the ratios of the speed of a volumetric elastic shear mode for the substrate to the speed of a fundamental elastic shear mode for the piezoelectric layer, which must be less than 1.

In a fourth series of transducers, a silicon substrate (130) is used instead of the quartz glass of the first series, with all other parameters remaining unchanged.

The simulation results are shown in Table 4 below.

TABLE 4

| Piezoelectric material | LiTaO₃ | LiTaO₃ | LiNbO₃ | LiNbO₃ |
|---|---|---|---|---|
| and operating frequency | 4.8 GHz | 2.4 GHz | 4.8 GHz | 2.4 GHz |
| C(Subst) in m/s | 5845 | | | |
| C(Piezo) in m/s | 4.852 | 5.291 | 4.359 | 4.954 |
| C(Subst)/C(Piezo) | 1.20 | 1.10 | 1.34 | 1.18 |
| | (NOK) | (NOK) | (NOK) | (NOK) |
| Attenuation (Elec) | 2.77.10⁻³ | 1.51.10⁻¹ | 7.27.10⁻² | 2.47.10⁻¹ |
| in dB/λ | (OK) | (NOK) | (OK) | (NOK) |
| Attenuation (Piezo) | 2.25.10⁻⁴ | 2.06.10⁻⁵ | 1.25.10⁻⁵ | 2.20.10⁻⁵ |
| in dB/λ | (NOK) | (NOK) | (NOK) | (NOK) |
| Substrate status | NOK | NOK | NOK | NOK |

As with the AT-cut quartz substrate, we note that it is not possible to use silicon as a substrate for any of the SAW transducers under consideration, the substrates being rejected and their status then indicated as NOK.

Additional calculation results similar to those presented above validated the use of the following substrates: a gallium arsenide substrate and a commercial Planoptik Borofloat glass with a Young's modulus of 73 GPa, a Poisson's ratio of 0.23 and a density of 2380 kg/m³.

Further simulations show that the choice of substrate for the electrodes and piezoelectric layer is by no means intuitive. Table 5 below lists glasses and their physical properties (density p, longitudinal and transverse sound propagation velocities V_{L} and V_{T}, Young's modulus E and Poisson's ratio v).

TABLE 5

| Glass | ρ [kg/m³] | v_{L} [m/s] | v_{T} [m/s] | E [GPa] | v |
|---|---|---|---|---|---|
| Glass A | 4360 | 4127 | 2414 | 63 | 0.24 |
| Glass B | 5000 | 6020 | 2900 | 113 | 0.349 |
| Glass C | 2470 | 5500 | 3100 | 60 | 0.267 |
| Glass D | 2440 | 5565 | 3408 | 68 | 0.2 |
| Pyrex | 2230 | 5710 | 3494 | 65 | 0.201 |
| Glass E | 2365 | 5620 | 3520 | 69 | 0.177 |
| Planoptik Eagle XG | 2380 | — | 3531 | 73 | 0.23 |
| Planoptik Borofloat | 2200 | — | 3481 | 64 | 0.2 |

Table 6 and Table 7 below show the result of simulations for devices fitted with a lithium tantalum piezoelectric layer of 600 nm height h, and intended to operate at a wavelength λ with electrodes of height h satisfying, respectively, h/λ=15% and h/λ=30%. More specifically, these tables show for the glasses in Table 5 associated with Au gold, Mo molybdenum and AlCu_{2%} alloy electrodes the C(Subst)/C(Piezo) ratio of the C(Subst) speeds of a volumetric elastic shear mode for the substrate and C(Piezo) of the fundamental elastic shear mode for the piezoelectric layer, the attenuation Attn.Elec. of the elastic electrode mode in the substrate, the attenuation Attn. Cis. of the fundamental shear mode for the piezoelectric layer, and the ratio Attn. Cis./Attn. Elec. of the latter two.

TABLE 6

| Elec- | | C_{vol.sub}/ | Attn. Elec. | Attn. Cis. | Attn.Cis./ |
|---|---|---|---|---|---|
| trodes | Glass | C_{fond.piezo} | [dB/λ] | [dB/λ] | Attn.Elec. |
| AlCu_{2%} | Glass A | 0.46 | 6 (NOK) | — | — |
| AlCu_{2%} | Glass B | 0.51 | 6.7 (NOK) | — | — |
| AlCu_{2%} | Glass C | 0.65 | 2.70E−03 | 11.1 | 4111.1 |
| AlCu_{2%} | Glass D | 0.72 | 1.80E−02 | 12.6 | 700.0 |
| AlCu_{2%} | Pyrex | 0.75 | 2.40E−02 | 12.8 | 533.3 |
| Au | Pyrex | 1.48 (NOK) | 5.37E−02 | 1.07E−04 | 1.99E−03 |
| | | | | | (NOK) |
| Mo | Pyrex | 1.02 (NOK) | 1.64 (NOK) | 7.37E−05 | 4.49E−05 |
| | | | | (NOK) | (NOK) |
| AlCu_{2%} | Glass E | 0.75 | 3.00E−02 | 12.6 | 420.0 |
| AlCu_{2%} | Planoptik | 0.75 | 1.41E−02 | 5.4 | 383.0 |
| | Eagle XG | | | | |
| AlCu_{2%} | Planoptik | 0.74 | 4.24E−03 | 3.53 | 832.5 |
| | Borofloat | | | | |
| Au | Planoptik | 1.49 (NOK) | 5.02E−02 | 1.06E−04 | 2.11E−03 |
| | Eagle XG | | | (NOK) | (NOK) |

TABLE 7

| Elec- | | C_{vol.sub}/ | Attn. Elec. | Attn. Cis. | Attn.Cis./ |
|---|---|---|---|---|---|
| trodes | Glass | C_{fond.piezo} | [dB/λ] | [dB/λ] | Attn.Elec. |
| AlCu_{2%} | Glass A | 0.49 | 1.9/NOK | 7.5 | 3.9 (NOK) |
| AlCu_{2%} | Glass B | 0.58 | 1.9/NOK | 6.5 | 3.4 (NOK) |
| AlCu_{2%} | Glass C | 0.66 | 2.00E−02 | 8.5 | 410.0 |
| AlCu_{2%} | Glass D | 0.72 | 1.00E−02 | 8.4 | 840.0 |
| AlCu_{2%} | Pyrex | 0.75 | 9.50E−03 | 8.2 | 863.2 |
| Au | Pyrex | 1.57 (NOK) | 4.60E−02 | 1.13E−03 | 2.46E−02 |
| | | | | (NOK) | (NOK) |
| Mo | Pyrex | 1.04 (NOK) | 7.87E−01/ | 7.45E−04 | 9.47E−04 |
| | | | NOK | (NOK) | (NOK) |
| AlCu_{2%} | Glass E | 0.75 | 9.00E−03 | 8.4 | 9.33E+02 |
| AlCu_{2%} | Planoptik | 0.75 | 3.77E−03 | 3.66 | 970.8 |
| | Eagle XG | | | | |
| AlCu_{2%} | Planoptik | 0.74 | 9.48E−03 | 5.56 | 586.5 |
| | Borofloat | | | | |
| Au | Planoptik | 1.59 (NOK) | 4.60E−02 | 2.45E−06 | 5.33E−05 |
| | Eagle XG | | | (NOK) | (NOK) |

The “NOK” comments indicate that the associated values prohibit the corresponding substrate from being used for an electrode mode-based SAW device according to the criteria of speed ratio, electrode elastic mode attenuation, piezoelectric layer fundamental shear mode attenuation, and attenuation ratio defined herein.

According to the criteria defined in this document, only a substrate made of one of the following glasses: C, D, E, Planoptik Eagle XG, Planoptik Borofloat and Pyrex, combined with electrodes made of a 2% copper-aluminum alloy AlCu_{2%}, provide a spectral purity of frequency response such that the fundamental shear mode is attenuated (propagation losses greater than 1 dB/λ), with a guided electrode mode (propagation losses less than 0.1 dB/λ). For each configuration meeting these criteria, the ratio between the attenuation of the fundamental shear mode and the electrode mode is at least greater than 10.

Furthermore, the fact that for the same type of glass, the nature of the electrode determines whether or not the criteria relating to (i) the attenuation of an electrode elastic mode in the piezoelectric layer and (ii) the speed ratio between a volumetric elastic shear mode for the substrate and a fundamental elastic shear mode for the piezoelectric layer are met, indicates that the substrate, electrodes, and piezoelectric layer must be matched. This match is contained in satisfying the two criteria (i) and (ii) recalled above.

These criteria make it possible to select, as a function of each other, the materials to be used for the substrate, electrodes and piezoelectric layer of an elastic surface-wave device based on the excitation of an electrode mode in such a way as to present a sufficiently pure spectral response to meet a contemplated application. It should also be noted that the phenomena used to attenuate the fundamental shear mode for the piezoelectric layer have no effect on the electrode mode.

### Exemplary Application 1

To show the influence of the fundamental shear mode for the piezoelectric layer in the case of a device resulting from a suitable choice of substrate, the theoretical transfer function (parameter S₂₁) of a conventional 600 ladder SAW filter with twelve identical 620 resonators connected in ladder fashion (eight in series and four in parallel) between a 630 SAW input and a 640 SAW output, as shown in FIG. 6, has been calculated.

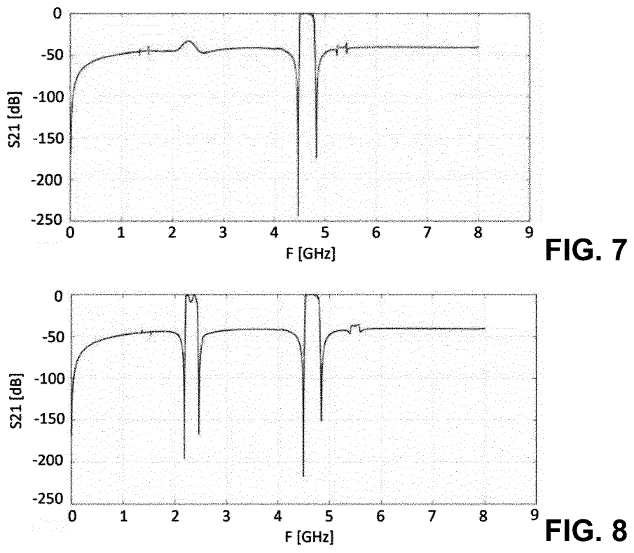

FIG. 7 shows the theoretical transfer function of such a filter, made up of resonators designed to operate at 4.8 GHz and comprising a quartz glass substrate with a LiTaO₃ piezoelectric layer and AlCu_{2%} alloy electrodes.

As shown in Table 1, quartz glass is considered an acceptable material for forming the substrate.

The signature of the fundamental shear mode for the piezoelectric layer appears at around 2.4 GHz and increases rejection to −34 dB.

### Exemplary Application 2

To show the influence of the fundamental shear mode for the piezoelectric layer in the case of a device resulting from an inappropriate choice of substrate, a second application example calculations were made on a device similar to that described in Example 1, but wherein the resonator substrate is formed from AT-cut quartz.

As seen in Table 3, AT-cut quartz is not considered acceptable for forming the substrate, as the attenuation of the fundamental shear mode for the piezoelectric layer in the substrate is insufficient.

FIG. 8 shows the theoretical transfer function of such a filter.

The signature of the fundamental shear mode for the piezoelectric layer appears at around 2.4 GHz and increases rejection to nearly 0 dB.

Comparison with application Example 1 makes it clear that the attenuation of the piezoelectric layer mode is insufficient, greatly degraded compared to the previous application example, and disturbs the filter response, with rejection rising to nearly 0 dB.

Of course, the disclosure is not limited to the above description, and it is possible to add variants without departing from the scope of the invention as defined by the claims.

1. An elastic surface wave device, comprising: a piezoelectric layer, electrodes embedded in the piezoelectric layer, and a substrate supporting the piezoelectric layer and the electrodes, wherein the substrate satisfies the following two conditions:
an attenuation of an elastic mode having an electrode in the piezoelectric layer is less than 0.1 dB/λ; and
a speed ratio between a volumetric elastic shear mode for the substrate and a fundamental elastic shear mode for the piezoelectric layer is smaller than a predetermined speed ratio value equal to 1 or less, the substrate being chosen from among gallium arsenide and a glass having a Young's modulus of between 60 GPa and 180 GPa, a Poisson's ratio of between 0.15 and 0.35, and a density of between 2000 kg/m³ and 6000 kg/m³.

2. The device of claim 1, wherein a ratio of an attenuation of the fundamental elastic shear mode for the piezoelectric layer to the attenuation of the electrode elastic mode is greater than 10.

3. The device of claim 2, wherein the electrodes pass completely through the piezoelectric layer.

4. The device of claim 3, wherein the substrate comprises a glass having a Young's modulus of between 60 GPa and 80 GPa, a Poisson's ratio of between 0.15 and 0.25, and a density of between 2100 kg/m³ and 2400 kg/m³.

5. The device of claim 3, wherein the substrate comprises gallium arsenide.

6. The device of claim 1, wherein the predetermined speed ratio value is equal to 0.9.

7. The device of claim 1, wherein the attenuation of the electrode elastic mode is defined by the formula
$$Attn = - 40 π \frac{π}{π - Δ} \frac{{f}_{h} - {f}_{b}}{{f}_{h} + {f}_{b}} log ( e )$$
where, for an electrode excitation generating a propagating mode of an elastic shear wave, Δ is an acoustic reflection coefficient per electrode, the log function represents the decimal logarithm such that log (e) ~0.434 and fₕ and f_{b} are frequencies associated with a resonance of the elastic shear wave at which an electrical susceptance of the elastic shear wave device reaches its highest and lowest points, respectively.

8. A method for determining the matching of a substrate to an elastic surface wave device comprising a piezoelectric layer, electrodes embedded in the piezoelectric layer and the substrate, the method being implemented by way of a computer system, the method comprising emitting a signal representative of a matching of the substrate to the elastic surface wave device, when:
an attenuation of an electrode elastic mode in the piezoelectric layer is less than 0.1 dB/λ; and
a ratio between a speed of a volumetric elastic shear mode for the substrate and a fundamental elastic shear mode for the piezoelectric layer is smaller than a predetermined speed ratio having a value equal to 1 or less.

9. The method of claim 8, wherein the computer system comprises a computer calculation unit and a computer memory database functionally in communication with the computer calculation unit and storing a database storing parameters relating to a geometry and nature of the electrodes, the piezoelectric layer, and the substrate, the computer calculation unit implementing the following steps:
retrieving data from the computer memory database, the data including parameters relating to the geometry and nature of the electrodes, the piezoelectric layer and the substrate;
calculating the attenuation of an elastic electrode mode in the piezoelectric layer, based on the retrieved data;
comparing the attenuation of the elastic electrode mode in the piezoelectric layer with a predefined attenuation value of 0.1 dB/λ;
calculating a speed ratio between a volumetric elastic shear mode for the substrate and a fundamental elastic shear mode for the piezoelectric layer, from the retrieved data;
comparing the speed ratio with a predetermined speed ratio value equal to 1 or less;
emitting the signal representative of a matching of the substrate to the elastic surface wave device, when:
the attenuation of the electrode elastic mode in the substrate is smaller than the predefined attenuation value; and
the speed ratio is smaller than the predetermined speed ratio value.

10. The method of claim 8, wherein the predetermined speed ratio value is equal to 0.9.

11. The method of claim 8, wherein the attenuation is defined by the formula
$$Attn = - 40 π \frac{π}{π - Δ} \frac{{f}_{h} - {f}_{b}}{{f}_{h} + {f}_{b}} log ( e )$$
where, for an electrode excitation generating a propagating mode of an elastic shear wave, Δ is an acoustic reflection coefficient per electrode, the log function represents the decimal logarithm such that log (e) ~0.434 and fₕ and f_{b} are frequencies associated with a resonance of the elastic shear wave at which an electrical susceptance of the elastic surface wave device reaches its highest and lowest point, respectively.

12. A method of manufacturing an elastic surface wave device comprising a piezoelectric layer, electrodes embedded in the piezoelectric layer and a substrate, wherein the method comprises determining the matching of a substrate material in accordance with the method of claim 8.

13. The device of claim 1, wherein the electrodes pass completely through the piezoelectric layer.

14. The device of claim 1, wherein the substrate comprises a glass having a Young's modulus of between 60 GPa and 80 GPa, a Poisson's ratio of between 0.15 and 0.25, and a density of between 2100 kg/m³ and 2400 kg/m³.

15. The device of claim 1, wherein the substrate comprises gallium arsenide.

16. The device of claim 4, wherein the predetermined speed ratio value is equal to 0.9.

17. The device of claim 16, wherein the attenuation of the electrode elastic mode is defined by the formula
$$Attn = - 40 π \frac{π}{π - Δ} \frac{{f}_{h} - {f}_{b}}{{f}_{h} + {f}_{b}} log ( e )$$
where for an electrode excitation generating a propagating mode of an elastic shear wave, Δ is an acoustic reflection coefficient per electrode, the log function represents the decimal logarithm such that log (e) ~0.434 and fₕ and f_{b} are frequencies associated with a resonance of the elastic shear wave at which an electrical susceptance of the elastic shear wave device reaches its highest and lowest points, respectively.

18. The device of claim 5, wherein the predetermined speed ratio value is equal to 0.9.

19. The device of claim 18, wherein the attenuation of the electrode elastic mode is defined by the formula
$$Attn = - 40 π \frac{π}{π - Δ} \frac{{f}_{h} - {f}_{b}}{{f}_{h} + {f}_{b}} log ( e )$$
where, for an electrode excitation generating a propagating mode of an elastic shear wave, Δ is an acoustic reflection coefficient per electrode, the log function represents the decimal logarithm such that log (e) ~0.434 and fₕ and f_{b} are frequencies associated with a resonance of the elastic shear wave at which an electrical susceptance of the elastic shear wave device reaches its highest and lowest points, respectively.
